(19) United States
(12) Patent Application Publication
(10) Pub. No.: US 2024/0241451 A1
(43) Pub. Date: Jul. 18, 2024

(54) METHOD OF MEASURING OVERLAY AND SEMICONDUCTOR DEVICE MANUFACTURED USING THE SAME

(71) Applicant: SAMSUNG ELECTRONICS CO., LTD., Suwon-si (KR)

(72) Inventors: Daehee LEE, Suwon-si (KR); Sangwon PARK, Suwon-si (KR); Kyeonga KIM, Suwon-si (KR); Jieun PARK, Suwon-si (KR); Byeong-Hwan SON, Suwon-si (KR)

(21) Appl. No.: 18/528,998

(22) Filed: Dec. 5, 2023

(30) Foreign Application Priority Data
Jan. 16, 2023 (KR) 10-2023-0006224

(51) Int. Cl. G03F 7/00; G03F 1/42; G03F 1/44; H01L 21/266

(52) U.S. Cl. CPC G03F 7/70633; G03F 1/42; G03F 1/44; G03F 7/70683; H01L 21/266

(57) ABSTRACT

A method of measuring overlay, including forming an active region on a cell region of a substrate and forming at least one overlay key structure on a scribe lane region of the substrate, forming a first mask pattern on the active region and forming a first sub-pattern on the overlay key structure, checking an alignment using the first sub-pattern, performing a first ion implantation process into the substrate, forming a second mask pattern on the active region and forming a second sub-pattern on the overlay key structure, checking the alignment using the second sub-pattern, and performing a second ion implantation process into the substrate, wherein a second width of the second sub-pattern is greater than a first width of the first sub-pattern.

### CROSS-REFERENCE TO RELATED APPLICATIONS

Korean Patent Application No. 10-2023-0006224, filed on Jan. 16, 2023, in the Korean Intellectual Property Office, is incorporated by reference herein in its entirety.

### BACKGROUND

### 1. Field

A method of measuring overlay and a semiconductor device including an overlay key structure is disclosed.

### 2. Description of the Related Art

Due to their small-sized, multifunctional, and/or low-cost characteristics, semiconductor devices are widely used in the electronic industry. The semiconductor devices may be classified into a memory device for storing data, a logic device for processing data, and a hybrid device including both memory and logic elements.

### SUMMARY

Embodiments are directed to a method of measuring overlay, including forming an active region on a cell region of a substrate and forming at least one overlay key structure on a scribe lane region of the substrate, forming a first mask pattern on the active region and forming a first sub-pattern on the overlay key structure, checking an alignment using the first sub-pattern, performing a first ion implantation process into the substrate, forming a second mask pattern on the active region and forming a second sub-pattern on the overlay key structure, checking the alignment using the second sub-pattern, and performing a second ion implantation process into the substrate, wherein a second width of the second sub-pattern is greater than a first width of the first sub-pattern.

Embodiments are directed to a semiconductor device, including a substrate including a key region, and an overlay key structure on the key region, wherein the overlay key structure includes a sub-pattern region and a plurality of main patterns spaced apart from each other, each of the plurality of main patterns being spaced apart from the sub-pattern region, the sub-pattern region including a first region provided in a center of the overlay key structure, a second region adjacent to the first region and surrounding the first region, and a third region between the second region and the plurality of main patterns, a third dopant concentration in the third region being greater than a first dopant concentration in the first region and a second dopant concentration in the second region.

Embodiments are directed to a three-dimensional semiconductor memory device, including a substrate including a cell array region, a contact region, and a scribe lane region, a peripheral circuit structure on the cell array region and the contact region, and a cell array structure on the peripheral circuit structure, and an overlay key structure on the scribe lane region, the cell array structure including a stack structure including interlayer insulating layers alternately and repeatedly stacked on the peripheral circuit structure and gate electrodes between the interlayer insulating layers, and vertical channel structures provided in vertical channel holes penetrating the stack structure, each of the vertical channel structures including a charge storage layer, a tunneling insulating layer, and a vertical semiconductor pattern sequentially covering inner walls of each of the vertical channel holes, the overlay key structure including a sub-pattern region and a main pattern spaced apart from the sub-pattern region, and a buried pattern on the main pattern, and a dopant concentration of the sub-pattern region gradually increasing from a center thereof toward the main pattern.

### BRIEF DESCRIPTION OF THE DRAWINGS

Features will become apparent to those of skill in the art by describing in detail exemplary embodiments with reference to the attached drawings, in which:

FIG. 1 is a flowchart showing steps in a method of measuring overlay according to an example embodiment.

FIG. 2 is a plan view showing a wafer substrate according to an example embodiment.

FIG. 3 is a plan view showing an overlay key structure including a first sub-pattern according to an example embodiment.

FIG. 4A is a cross-sectional view taken along line A-A′ in FIG. 3 showing a sub-pattern on a substrate between second and fourth main patterns.

FIG. 4B is a cross-sectional view taken along line B-B′ in FIG. 3 showing a sub-pattern on a substrate between first and third main patterns.

FIG. 5A is a cross-sectional view taken along line I-I′ in FIG. 2 showing a cell region including a first mask pattern.

FIG. 5B is a cross-sectional view taken along line II-II′ in FIG. 2 showing a key region including a first sub-pattern.

FIG. 6A is a plan view showing an overlay key structure, including a first sub-pattern having equal lengths between edge portions of the first sub-pattern and an edge portion of each of the main patterns.

FIG. 6B is a plan view showing an overlay key structure, including a first sub-pattern having a fifth length greater than a seventh length, and a sixth length greater than an eighth length.

FIG. 7A is a cross-sectional view taken along line I-I′ in FIG. 2 showing a first ion implantation process in a cell region, including a first mask pattern.

FIG. 7B is a cross-sectional view taken along line II-II′ in FIG. 2 showing a first ion implantation process in a key region, including a first sub-pattern.

FIG. 8A is a cross-sectional view taken along line I-I′ in FIG. 2 showing a second mask pattern on a cell region.

FIG. 8B is a cross-sectional view taken along line II-II′ in FIG. 2 showing a second sub-pattern in a key region.

FIG. 9A is a cross-sectional view taken along line II-II′ in FIG. 2 showing a second sub-pattern blocking a portion of the first dopant region in a key region.

FIG. 9B is a plan view showing an overlay key structure, including a second sub-pattern according to an example embodiment.

FIG. 10A is a cross-sectional view taken along line II-II′ in FIG. 2 showing a third sub-pattern blocking a portion of the first dopant region in a key region.

FIG. 10B is a plan view showing an overlay key structure, including a region deteriorated by the first ion implantation process.

FIG. 11A shows a third image of an overlay key structure obtained by photographing the overlay key structure with a CCD camera while the second sub-pattern is formed.

FIG. 11B shows a fourth image of an overlay key structure obtained by photographing the overlay key structure with a CCD camera while the third sub-pattern is formed.

FIG. 12 is a plan view showing an overlay key structure, including a second sub-pattern having equal lengths between edge portions of the second sub-pattern and an edge portion of each of the main patterns.

FIG. 13A is a cross-sectional view taken along line I-I′ in FIG. 2 showing a second ion implantation process in a cell region, including a second mask pattern.

FIG. 13B is a cross-sectional view taken along line II-II′ in FIG. 2 showing a second ion implantation process in a key region, including a second sub-pattern.

FIG. 14 is a plan view showing a semiconductor memory device, including an overlay key structure according to an example embodiment.

FIG. 15 is a cross-sectional view taken along line I-I′ in FIG. 14 showing a cell array region, including a cell array structure and a peripheral circuit structure on a first substrate.

FIG. 16 is a cross-sectional view taken along line II-II′ in FIG. 14 showing a cell array region, including a cell array structure and a peripheral circuit structure on a first substrate.

FIG. 17 is a cross-sectional view showing a dopant concentration for each region of an overlay key structure.

FIG. 18 is a view showing a conventional key region of a semiconductor memory device according to an example embodiment.

### DETAILED DESCRIPTION

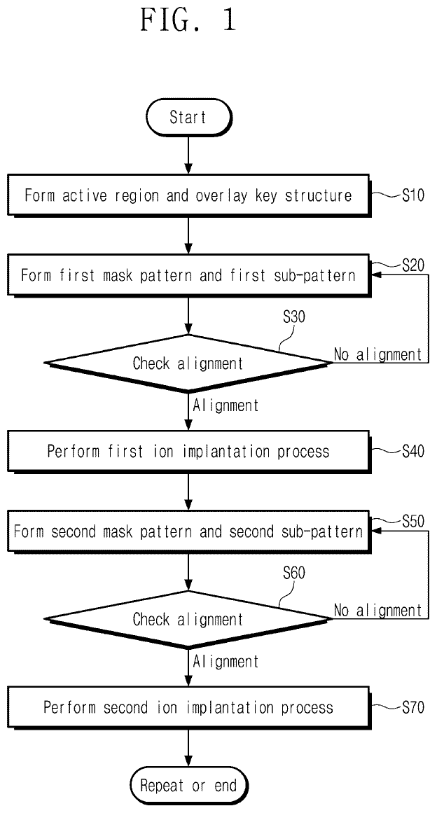

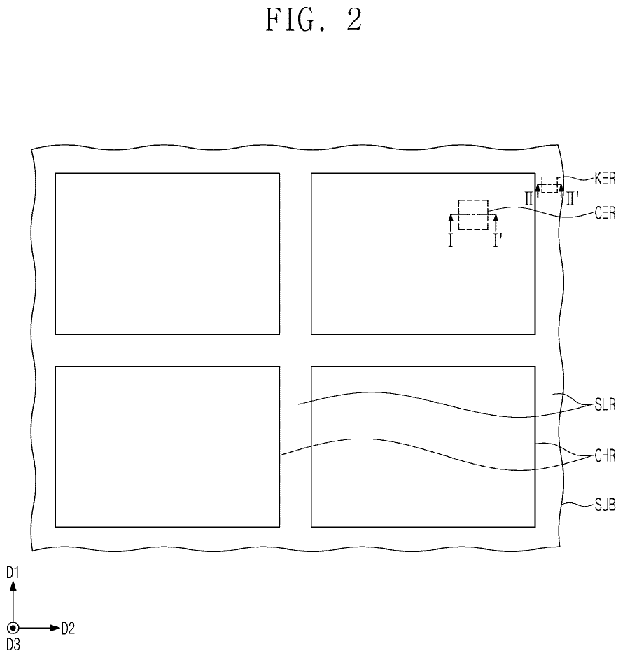

FIG. 1 is a flowchart showing steps in a method of measuring overlay according to an example embodiment. FIG. 2 is a plan view showing a wafer substrate according to an example embodiment.

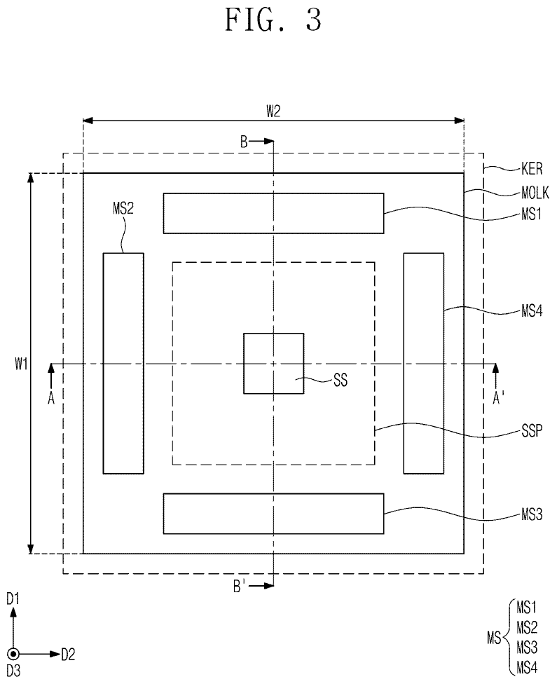

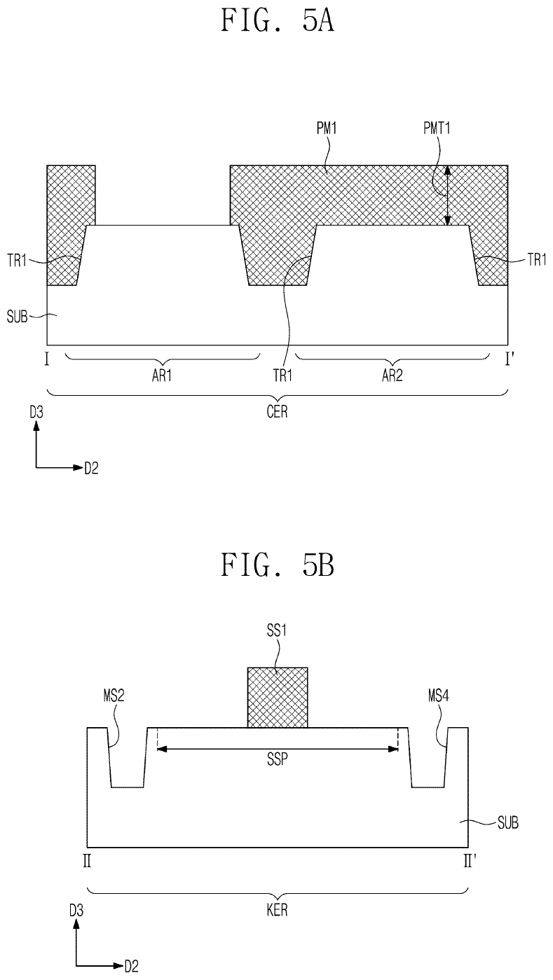

Referring to FIGS. 1 and 2, forming an active region on a cell region of a substrate and forming at least one overlay key structure on a scribe lane region of the substrate in S10 may be forming active regions (AR1 and AR2 of FIG. 5A) on a cell region CER of a substrate SUB and forming at least one overlay key structure (MOLK of FIG. 3) corresponding to the active regions AR1 and AR2 on a scribe lane region SLR of the substrate SUB, respectively. The forming of the active region on the cell region of the substrate and the forming of the at least one overlay key structure on the scribe lane of the substate in S10 may be referred to as forming a structure in S10.

In an implementation, the substrate SUB may include a plurality of two-dimensionally arranged chip regions CHR and a scribe lane region SLR between the chip regions CHR. After the semiconductor process is completed, the chip regions CHR may be separated into dies (i.e., semiconductor chips) by cutting the scribe lane region SLR. The chip region CHR may include a cell region CER in which memory cells may be disposed. The scribe lane region SLR may include a key region KER in which an align key or an overlay key is disposed. In other words, one overlay key structure (MOLK in FIG. 3) may be formed on the key region KER of the scribe lane region SLR.

The chip regions CHR may form rows and columns and may be two-dimensionally arranged with the scribe lane region SLR therebetween. The columns may be parallel to a first direction D1. The rows may be parallel to a second direction D2. Herein, the first direction D1 may cross the second direction D2. For example, the second direction D2 may be substantially perpendicular to the first direction D1. A third direction D3 may be perpendicular to the first direction D1 and the second direction D2.

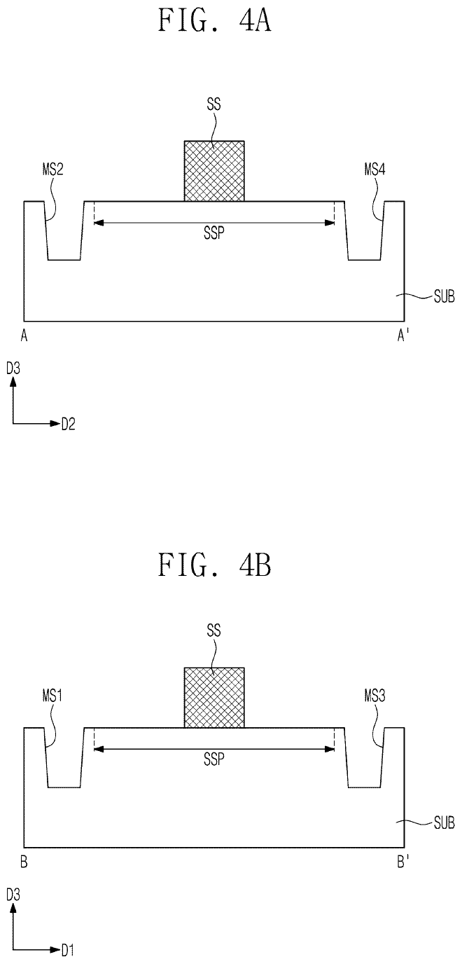

FIG. 3 is a plan view showing an overlay key structure including a first sub-pattern according to an example embodiment. FIG. 4A is a cross-sectional view taken along line A-A′ of FIG. 3 showing a sub-pattern on a substrate between second and fourth main patterns. FIG. 4B is a cross-sectional view taken along line B-B′ of FIG. 3 showing a sub-pattern on a substrate between first and third main patterns. Referring to FIGS. 3 to 4B, the forming of the overlay key structure in the forming of the structure in S10 may be forming one overlay key structure MOLK on the key region KER. The overlay key structure MOLK may be used to check alignment of a mask pattern on the cell region CER before repeated ion implantation processes are performed. The repeated ion implantation processes may be implantation processes for forming a well of a semiconductor device.

A width of the overlay key structure MOLK in the first direction D1 may be defined as a first width W1, and a width of the overlay key structure MOLK in the second direction D2 may be defined as a second width W2. The first width W1 and the second width W2 may be equal. The first and second widths W1 and W2 may range from 32.5 μm to 37.5 μm. Preferably, the first width W1 and the second width W2 may be 35 μm. The overlay key structure MOLK may have a square or rectangular shape in a plan view.

In an implementation, the forming of the overlay key structure MOLK may include forming trenches spaced apart by a certain interval on the scribe lane region SLR and forming a sub-pattern region SSP between the trenches. The trenches spaced apart by a certain interval on the scribe lane region SLR may be equally spaced apart (MS in FIG. 3). The trenches may be a plurality of main patterns MS. The sub-pattern region SSP may be a region in which sub-patterns SS are disposed before an ion implantation process described later is performed. The sub-pattern region SSP may be a region positioned at a center of the overlay key structure MOLK in a plan view.

The overlay key structure MOLK may include a sub-pattern region SSP and a plurality of main patterns MS. The plurality of main patterns MS may be arranged with the sub-pattern region SSP therebetween. Each of the main patterns MS may be spaced apart from each other. Each of the main patterns MS may be spaced apart from the sub-pattern region SSP. The plurality of main patterns MS may be patterns embedded in the substrate SUB.

In an implementation, the plurality of main patterns MS may include a first main pattern MS1, a second main pattern MS2, a third main pattern MS3, and a fourth main pattern MS4. The first main pattern MS1 and the third main pattern MS3 may be arranged in the first direction D1. The third main pattern MS3 may be on an opposite side of the first main pattern MS1 with the sub-pattern region SSP therebetween in the first direction D1. The second main pattern MS2 and the fourth main pattern MS4 may be arranged in the second direction D2. The fourth main pattern MS4 may be on an opposite side of the second main pattern MS2 with the sub-pattern region SSP therebetween in the second direction D2.

FIG. 5A is a cross-sectional view taken along line I-I′ of FIG. 2 showing a cell region including a first mask pattern. FIG. 5B is a cross-sectional view taken along line II-II′ of FIG. 2 showing a key region including a first sub-pattern. Referring to FIGS. 1, 5A and 5B, forming a first mask pattern on the active region and forming a first sub-pattern on the overlay key structure in S20 may include forming a first mask pattern PM1 which may not block the first active region AR1 and may block the second active region AR2 and the trench TR1 and forming a first sub-pattern SS1 on the sub-pattern region SSP on the key region KER. The forming of the first mask pattern on the active region and the first sub-pattern on the overlay key structure in S20 may be referred to as forming a first pattern in S20.

In the forming of the first pattern in S20, the first mask pattern PM1 and the first sub-pattern SS1 may be simultaneously formed. This may be because the overlay key structure (MOLK in FIG. 3) is used as an overlay mark corresponding to the active regions AR1 and AR2 on the cell region CER. That is, because all the plurality of cell regions CER of the substrate SUB cannot be measured, it may be confirmed whether the first mask pattern PM1 is properly formed at a desired location on the cell region CER using the overlay key structure (MOLK of FIG. 3).

Referring back to FIGS. 1 and 5B, the forming of the first pattern in S20 may include forming the first sub-pattern SS1 on a center of the overlay key structure (MOLK in FIG. 3) when viewed in a plan view. In an implementation, the first sub-pattern SS1 may be on a center of the sub-pattern region SSP.

The first mask pattern PM1 and the first sub-pattern SS1 may include a photoresist coated thereon. The first mask pattern PM1 and the first resonant pattern SS1 may include chemical amplification resist (CAR). For example, the CAR may be poly-hydroxy styrene resist.

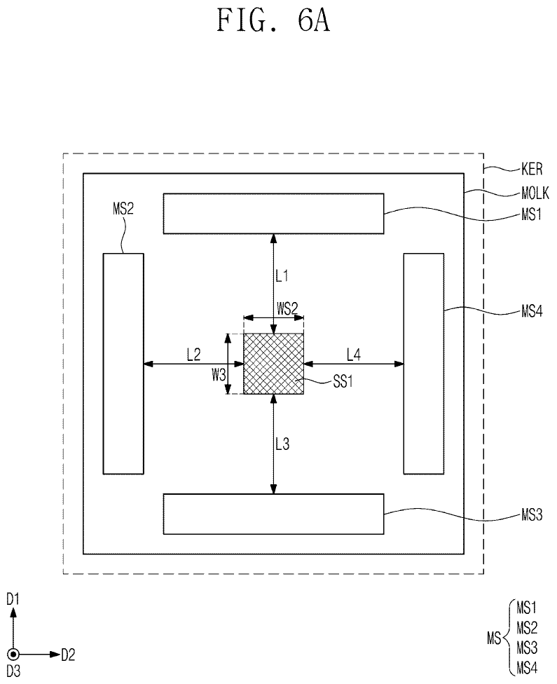

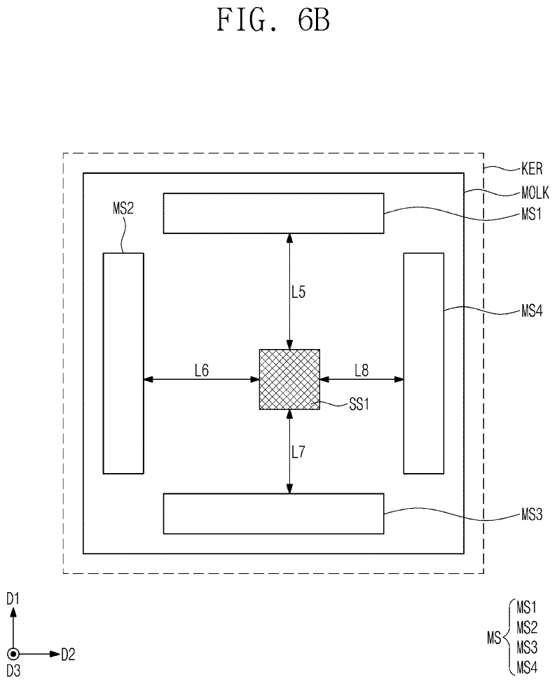

FIG. 6A is a plan view showing an overlay key structure including a first sub-pattern having equal lengths between edge portions of the first sub-pattern and an edge portion of each of the main patterns. Referring to FIGS. 1 and 6A, checking alignment using the first sub-pattern in S30 may include obtaining a first image of the overlay key structure MOLK and checking whether the first son pattern SS1 is in the center of the overlay key structure MOLK based on the first image. The checking of the alignment using the first sub-pattern SS1 in S30 may be referred to as checking a first alignment.

The obtaining of the first image in the checking of the first alignment in S30 may include obtaining an image of the overlay key structure MOLK in which the first sub-pattern SS1 is disposed. The first image may be an image captured by a CCD camera. It may be possible to check a size of the first sub-pattern SS1 through the first image. The size of the first sub-pattern SS1 may be defined as a value obtained by multiplying a width in the first direction D1 by a width in the second direction D2.

The width of the first sub-pattern SS1 in the first direction D1 may be defined as a third width W3, and the width of the first sub-pattern SS1 in the second direction D2 may be defined as a fourth width W4. The third width W3 and the fourth width W4 may be equal. The third and fourth widths W3 and W4 may range from 7975 nm to 8025 nm. Preferably, the third width W3 and the fourth width W4 may be 8 μm or 8000 nm. The first sub-pattern SS1 may have a square or quadrangular shape when viewed in a plan view.

In the checking of the first alignment in S30, the checking whether the first sub-pattern SS1 is in the center of the overlay key structure MOLK based on the first image may include comparing lengths between the first sub-pattern SS1 and the plurality of main patterns MS.

A first length L1 between the first main pattern MS1 and the first sub-pattern SS1 may be measured. A second length L2 between the second main pattern MS2 and the first sub-pattern SS1 may be measured. A third length L3 between the third main pattern MS3 and the first sub-pattern SS1 may be measured. A fourth length L4 between the fourth main pattern MS4 and the first sub-pattern SS1 may be measured. In an implementation, each of the first to fourth lengths L1, L2, L3, and L4 may be a length between an edge portion of each of the main patterns MS and an edge portion of the first sub-pattern SS1 facing the edge portion. When the measured first to fourth lengths L1, L2, L3, and L4 are equal, it may be determined that the first sub-pattern SS1 is at a center of the overlay key structure MOLK.

FIG. 6B is a plan view showing an overlay key structure including a first sub-pattern having a fifth length greater than a seventh length and a sixth length greater than an eighth length. Referring to FIGS. 1 and 6B, checking alignment using the first sub-pattern in S30 may further include reworking a first mask pattern (PM1 in FIG. 5A) and a first sub-pattern SS1. The reforming may be performed when the first sub-pattern SS1 is not at the center of the overlay key structure MOLK.

A fifth length L5 between the first main pattern MS1 and the first sub-pattern SS1 may be measured. A sixth length L6 between the second main pattern MS2 and the first sub-pattern SS1 may be measured. A seventh length L7 between the third main pattern MS3 and the first sub-pattern SS1 may be measured. An eighth length L8 between the fourth main pattern MS4 and the first sub-pattern SS1 may be measured. When the measured fifth to eighth lengths L5, L6, L7, and L8 are compared and are different from each other, the first sub-pattern SS1 may not be at the center of the overlay key structure MOLK.

When the first sub-pattern SS1 is not at the center of the overlay key structure MOLK, the first mask pattern (PM1 in FIG. 5A) and the first sub-pattern SS1 may be removed by an ashing process. After performing the ashing process, the first mask pattern (PM1 in FIG. 5A) and the first sub-pattern SS1 may be reworked again. When the reworked first sub-pattern SS1 is not at the center of the overlay key structure MOLK, the reworking process may be repeated.

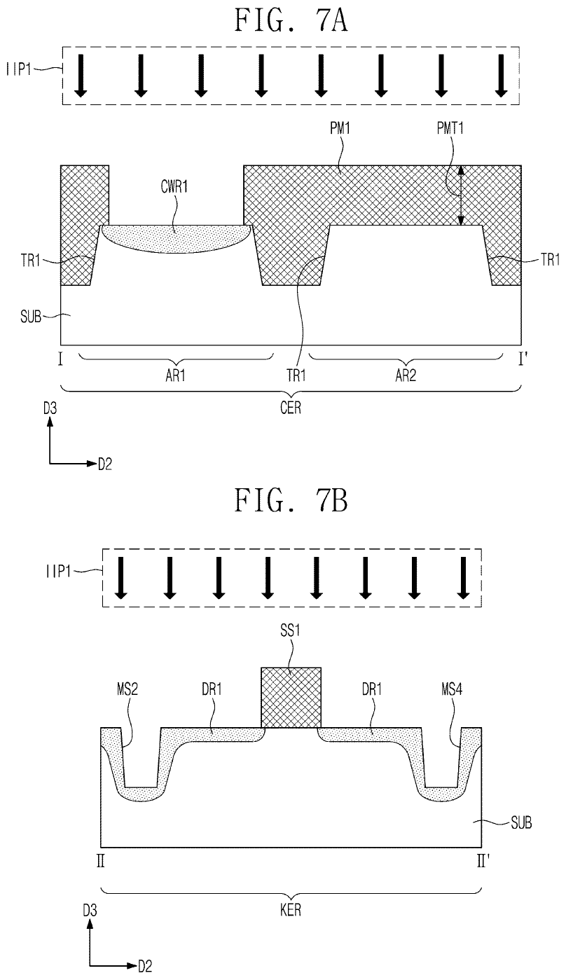

FIG. 7A is a cross-sectional view taken along line I-I′ of FIG. 2 showing a first ion implantation process in a cell region including a first mask pattern. FIG. 7B is a cross-sectional view taken along line II-II′ of FIG. 2 showing a first ion implantation process in a key region including a first sub-pattern. Referring to FIGS. 1, 7A, and 7B, performing a first ion implantation process toward the substrate in S40 may include performing a first ion implantation process IIP1 toward the cell region CER and the key region KER of the substrate SUB in the third direction D3. Performing the first ion implantation process toward the substrate in S40 may be referred to as a first ion implantation process in S40.

In the first ion implantation process in S40, the first mask pattern PM1 may block dopants implanted onto the cell region CER by the first ion implantation process IIP1. In an implementation, as the first active region AR1 is not blocked by the first mask pattern PM1 and is open, the first ion implantation region CWR1 may be formed in the first active region AR1. For example, the first ion implantation region CWR1 may be a triple well or a deep well. The second active region AR2 and the trench TR1 may be blocked by the first mask pattern PM1, and thus dopants may not be injected.

The first sub-pattern SS1 may block dopants injected into the key region KER. In an implementation, a first dopant region DR1 may be formed in a region not blocked by the first sub-pattern SS1 in the overlay key structure (MOLK of FIG. 6A) on the key region KER. A region below the first sub-pattern SS1 may be blocked, and thus dopants may not be implanted. A dopant may exist in a region adjacent to an edge of the first sub-pattern SS1 among regions under the first sub-pattern SS1 due to a diffusion phenomenon of the dopant included in the first dopant region DR1.

The dopant may be any one of an n-type impurity and a p-type impurity. The n-type impurity may be a group V element. For example, the n-type impurity may be phosphorus (P), arsenic (As), or antimony (Sb). The p-type impurity may be a Group III element. For example, the p-type impurity may be boron (B), gallium (Ga), or indium (In). The p-type impurity may be in s form of a molecule including boron (B). For example, the p-type impurity may be BF2.

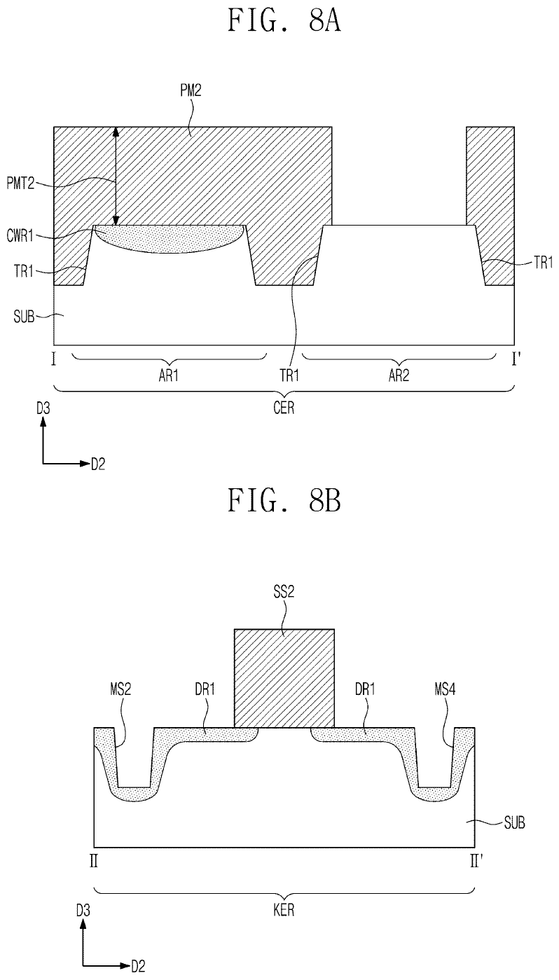

FIG. 8A is a cross-sectional view taken along line I-I′ of FIG. 2 showing a second mask pattern on a cell region. FIG. 8B is a cross-sectional view taken along line II-II′ of FIG. 2 showing a second sub-pattern in a key region. Referring to FIGS. 1, 8A, and 8B, forming a second mask pattern on an active region and forming a second sub-pattern on an overlay key structure in S50 may further include removing the first mask pattern (PM1 in FIG. 7A) and the first sub-pattern (SS1 in FIG. 7B) before forming the second mask pattern PM2 and the second sub-pattern SS2. The first mask pattern (PM1 in FIG. 7A) and the first sub-pattern (SS1 in FIG. 7B) may be removed by performing an ashing process.

The forming of the second mask pattern on the active region and the forming of the second sub-pattern on the overlay key structure in S50 include forming a second mask pattern PM2 which does not block the second active region AR2 on the cell region CER and blocks the first active region AR1 and the trench TR1 and forming a second sub-pattern SS2 on the sub-pattern region (SSP in FIG. 3) of the key region KER. The forming of the second mask pattern on the active region and the second sub-pattern on the overlay key structure in S50 may be referred to as forming a second pattern in S50.

The forming of the second pattern in S50 may be simultaneously forming the second mask pattern PM2 and the second sub-pattern SS2. This may be because the overlay key structure (MOLK in FIG. 3) may be used as an overlay mark corresponding to the active regions AR1 and AR2 on the cell region CER. That is, as all the plurality of cell regions CER of the substrate SUB cannot be measured, it may be confirmed whether the second mask pattern PM2 is properly formed at a desired position on the cell region CER using the overlay key structure (MOLK in FIG. 3).

Referring again to FIGS. 1 and 8B, the forming of the second sub-pattern SS2 in the forming of the second pattern in S50 may be positioning the sub-pattern SS2 on a center of the overlay key structure (MOLK in FIG. 3) when viewed in a plan view. In an implementation, the second sub-pattern SS2 may be on the center of the sub-pattern region (SSP in FIG. 3).

The second mask pattern PM2 and the second sub-pattern SS2 may include a coated photoresist. The second mask pattern PM2 and the second sub-pattern SS2 may include chemical amplification resist (CAR). For example, the chemical amplification resist may be poly-hydroxy styrene resist.

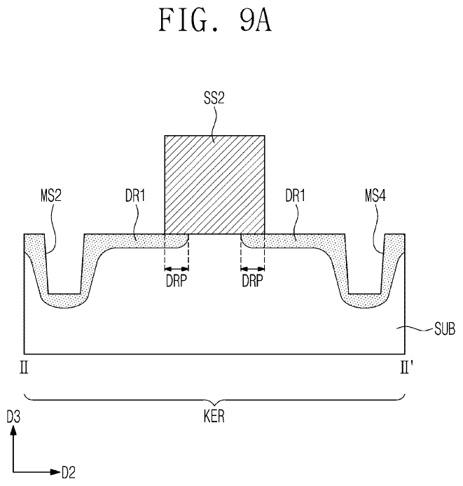

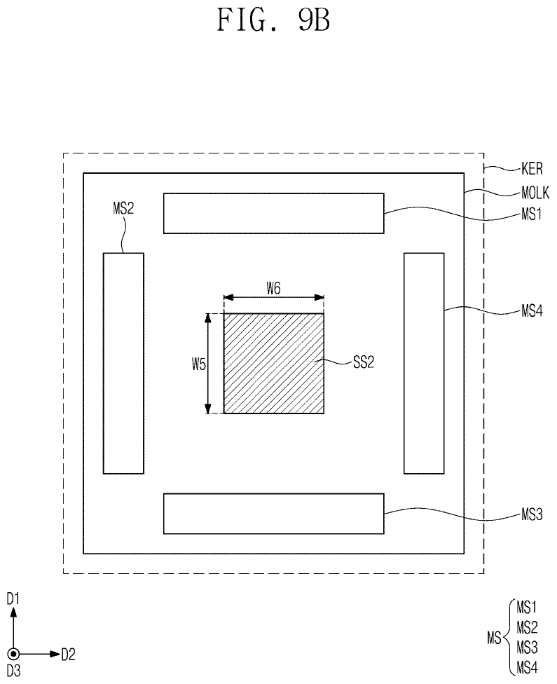

Referring to FIGS. 5A and 8A, a thickness of the first mask pattern PM1 may be defined as a first thickness PMT1, and a thickness of the second mask pattern PM2 may be defined as a second thickness PMT2. The first thickness PMT1 may be smaller than the second thickness PMT2. This may be to make a size of the second sub-pattern (SS2 in FIG. 8B) larger than a size of the first sub-pattern (SS1 in FIG. 5B). As the size of the second sub-pattern (SS2 in FIG. 8B) may be larger than the size of the first sub-pattern (SS1 in FIG. 5B), accuracy may be improved by checking a second alignment described later. Hereinafter, the reason why the accuracy of the method of measuring the overlay improves as the size of the second sub-pattern is greater than the size of the first sub-pattern will be described with reference to FIGS. 9A to 11B.

FIG. 9A is a cross-sectional view taken along line II-II′ of FIG. 2 showing a second sub-pattern blocking a portion of the first dopant region in a key region. FIG. 9B is a plan view showing an overlay key structure including a second sub-pattern according to an example embodiment.

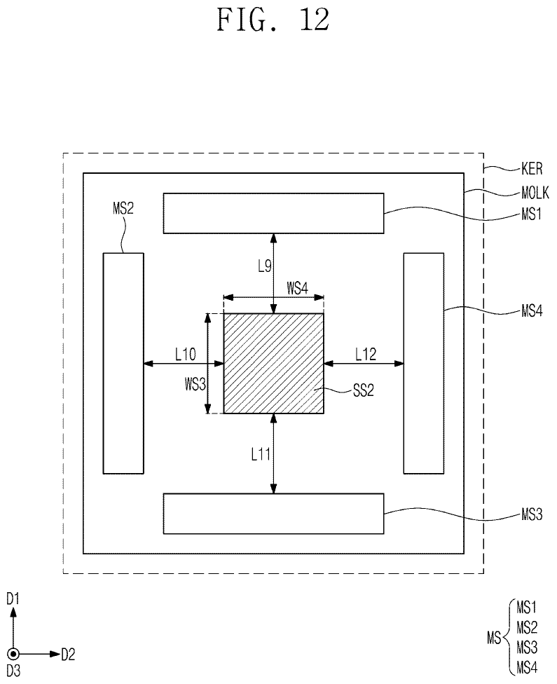

Referring to FIGS. 9A and 9B, the second sub-pattern SS2 may be formed on the overlay key structure MOLK of the key region KER. The second sub-pattern SS2 may block a portion DRP of the first dopant region DR1 by a first ion implantation process (IIP1 of FIG. 7B). This may be because a fifth width (W5 in FIG. 12) and a sixth width (W6 in FIG. 12) of the second sub-pattern SS2 are greater than the third width (W3 in FIG. 6A) and the fourth width (W4 in FIG. 6A) of the first sub-pattern (SS1 in FIG. 6A).

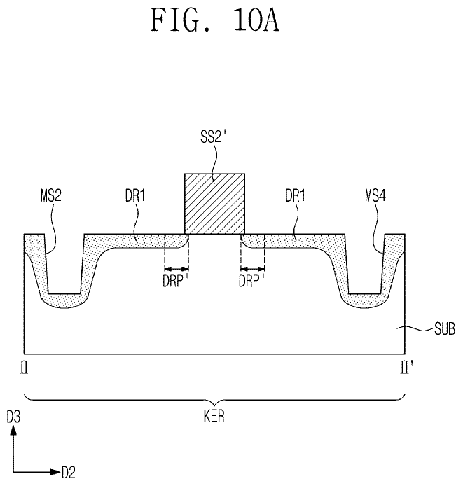

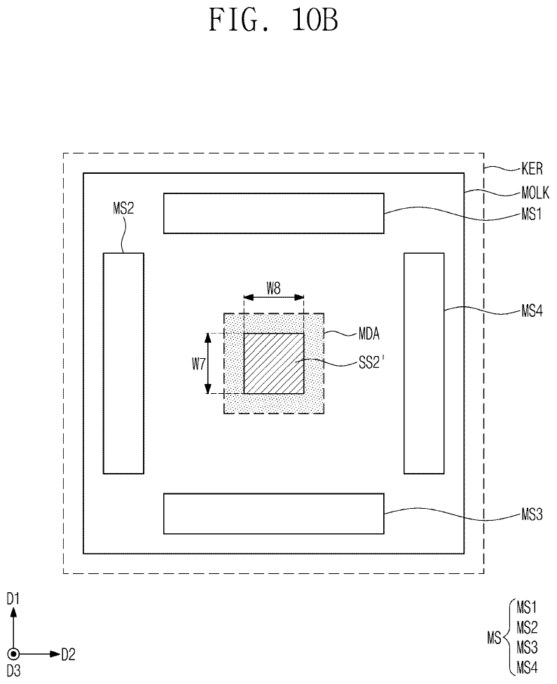

FIG. 10A is a cross-sectional view taken along line II-II′ of FIG. 2 showing a third sub-pattern blocking a portion of the first dopant region in a key region. FIG. 10B is a plan view showing an overlay key structure including a region deteriorated by the first ion implantation process. Referring to FIGS. 10A and 10B, a third sub-pattern SS2′ according to the conventional method of measuring the overlay may be formed on the overlay key structure MOLK of the key region KER. The third sub-pattern SS2′ cannot block the portion DRP′ of the first dopant region DR1 by the first ion implantation process (IIP1 of FIG. 7B). This may be because a seventh width W7 and an eighth width W8 of a third sub-pattern SS2′ are equal to the third width (W3 in FIG. 6A) and the fourth width (W4 in FIG. 6A) of the first sub-pattern (SS1 in FIG. 6A).

Referring back to FIGS. 9A to 10B, checking alignment using the sub-patterns SS2 and SS2′ may include obtaining an image of the overlay key structure MOLK and checking whether the sub-patterns SS2, SS2′ are in the center of the overlay key structure MOLK based on the image. As described above, the checking whether the sub-patterns SS2 and SS2′ are in the center may include measuring and comparing a length between an edge portion of each of the main pattern MS of the overlay key structure MOLK and an edge portion of the sub-patterns SS2 and SS2′ facing the edge portion.

When a region MDA deteriorated by the first ion implantation process (IIP1 in FIG. 7B) is not blocked, such as the third sub-pattern SS2′, it may be difficult to measure the length between the edge portion of each of the main patterns MO and an edge of the third sub-pattern SS2′. This may be because a brightness of an image used when checking the alignment is not constant for each region. That is, because a length is measured based on an image captured by a CCD camera, accuracy of overlay measurement may be improved as the brightness of the image is constant.

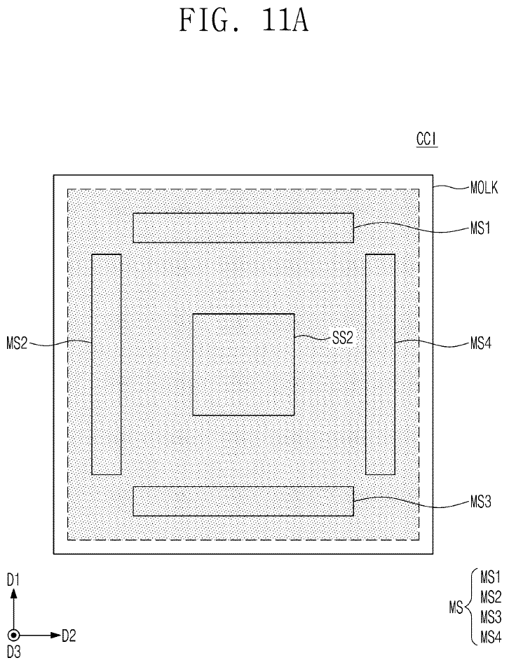

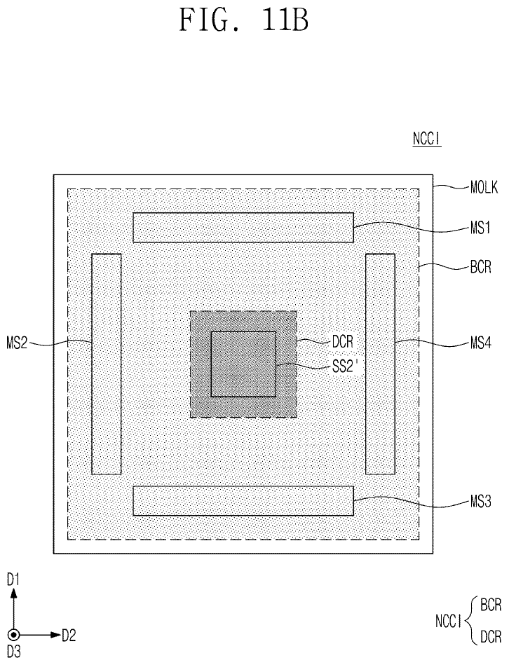

FIG. 11A shows a third image of an overlay key structure obtained by photographing the overlay key structure with a CCD camera while the second sub-pattern is formed. Referring to FIG. 11A, a third image CCI of the overlay key structure MOLK according to an example embodiment may be obtained. The third image CCI may be obtained by photographing the overlay key structure MOLK with a CCD camera while the second sub-pattern SS2 is formed. The third image CCI may have constant brightness. That is, contrast of the third image CCI may be constant.

FIG. 11B shows a fourth image of an overlay key structure obtained by photographing the overlay key structure with a CCD camera while the third sub-pattern is formed. Referring to FIG. 11B, a fourth image NCCI of the overlay key structure MOLK according to the conventional method of measuring the overlay may be obtained. The fourth image NCCI may be obtained by photographing the overlay key structure MOLK with a CCD camera while the third sub-pattern SS2′ is formed. The fourth image NCCI may have different brightness for each region. The fourth image NCCI may include a dark region DCR and a bright region BCR. The dark region DCR may include the third sub-pattern SS2′ and the deteriorated region (MDA in FIG. 10B) when viewed in a plan view. The bright region BCR may be a region other than the dark region DCR in the fourth image NCCI.

Referring to FIGS. 11A and 11B, because the brightness of the third image CCI is more constant than that of the fourth image NCCI, measuring the length between the edge portion of each of the main pattern MS and the edge portion of the second sub-pattern SS2 based on the third image CCI may be more accurate than measuring the length between the edge portion of each of the main patterns MS and the edge portion of the third son pattern SS2′ based on the fourth image NCCI. That is, the method of measuring the overlay may have improved accuracy according to an example embodiment.

FIG. 12 is a plan view showing an overlay key structure including a second sub-pattern having equal lengths between edge portions of the second sub-pattern and an edge portion of each of the main patterns. Referring to FIGS. 1 and 12, checking alignment using the second sub-pattern in S60 may include obtaining a second image for the overlay key structure MOLK and checking whether the second sub-pattern SS2 is in the center of the overlay key structure MOLK based on the second image. The checking the alignment using the second sub-pattern in S60 may be referred to as checking second alignment in S60.

The obtaining of the second image in the checking of the second alignment in S60 may be obtaining an image of the overlay key structure MOLK in a state in which the second sub-pattern SS2 may be disposed. The second image may be an image captured by a CCD camera. It may be possible to check a size of the first sub-pattern SS2 through the second image. The size of the second sub-pattern SS2 may be defined as a value obtained by multiplying a width in the first direction D1 by a width thereof in the second direction D2.

A width of the second sub-pattern SS2 in the first direction D1 may be defined as the fifth width W5, and a width of the second sub-pattern SS2 in the second direction D2 may be defined as the sixth width W6. The fifth width W5 and the sixth width W6 may be equal to each other. The fifth and sixth widths W5 and W6 may range from 8125 nm to 8175 nm. Preferably, the fifth and sixth widths W5 and W6 may be 8.15 μm or 8150 nm. The second sub-pattern SS2 may have a square or quadrangular shape when viewed in a plan view.

Referring to FIGS. 6A and 12, a difference between the fifth width W5 and the third width W3 may range from 125 nm to 175 nm. A difference between the sixth width W6 and the fourth width W4 may be between 125 nm and 175 nm. Preferably, the difference between the fifth width W5 and the third width W3 and the difference between the sixth width W6 and the fourth width W4 may be 150 nm.

The checking of the second alignment in S60, checking whether the second sub-pattern SS2 is in the center of the overlay key structure MOLK based on the second image may be comparing lengths between the second sub-pattern SS2 and the plurality of main patterns MS.

A ninth length L9 between the first main pattern MS1 and the second sub-pattern SS2 may be measured. A tenth length L10 between the second main pattern MS2 and the second sub-pattern SS2 may be measured. An eleventh length L11 between the third main pattern MS3 and the second sub-pattern SS2 may be measured. A twelfth length L12 between the fourth main pattern MS4 and the second sub-pattern SS2 may be measured. In an implementation, each of the ninth to twelfth lengths L9, L10, L11, and L12 may be a length between the edge portion of each of the main patterns MS and an edge portion of the second sub-pattern SS2 facing the edge portion.

When the measured ninth to twelfth lengths L9, L10, L11, and L12 are compared and are equal, it may be determined that the second sub-pattern SS2 is at the center of the overlay key structure MOLK.

The checking of the second alignment in S60 may further include reworking a second mask pattern (PM2 of FIG. 8A) and the second sub-pattern SS2. The reforming may be performed when the second sub-pattern SS2 is not at the center of the overlay key structure MOLK. The reforming may be performed through the same process as the reforming in the checking of the first alignment in S30.

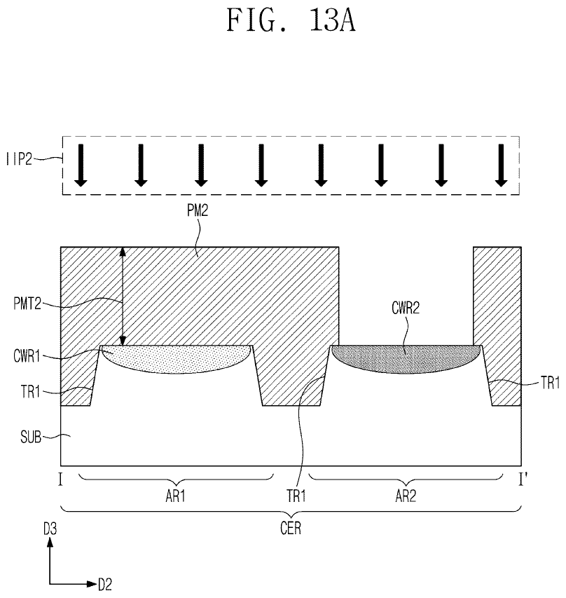

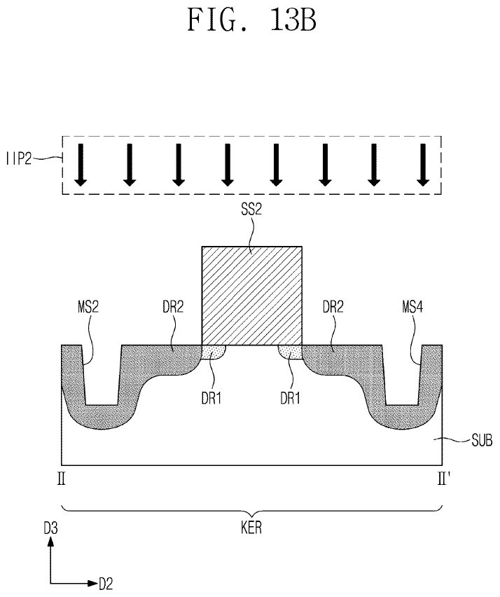

FIG. 13A is a cross-sectional view taken along line I-I′ of FIG. 2 showing a second ion implantation process in a cell region including a second mask pattern. FIG. 13B is a cross-sectional view taken along line II-II′ of FIG. 2 showing a second ion implantation process in a key region including a second sub-pattern. Referring to FIGS. 1, 13A, and 13B, performing the second ion implantation process toward the substrate in S70 may be performing the second ion implantation process IIP2 toward the cell region CER and key region KER of the substrate SUB in the third direction D3. The performing of the second ion implantation process toward the substrate in S70 may be referred to as a second ion implantation process in S70.

In the second ion implantation process in S70, a second mask pattern PM2 may block dopants implanted onto the cell region CER by the second ion implantation process IIP2. In an implementation, the second active region AR2 may not be blocked by the first mask pattern PM1 and be open, and thus the second ion implantation region CWR2 may be formed in the second active region AR2. For example, the second ion implantation region CWR2 may be a triple well, a deep well, or a threshold voltage adjusted region. The first active region AR1 and the trench TR1 may be blocked by the second mask pattern PM2, and thus dopants may not be injected thereon.

The second sub-pattern SS2 may block dopants injected into the key region KER. In an implementation, a second dopant region DR2 may be formed in a region not blocked by the second sub-pattern SS2 in the overlay key structure (MOLK of FIG. 6A) on the key region KER. A region under the second sub-pattern SS2 may be blocked, and thus dopants may not be implanted by the second ion implantation process IIP2. The second sub-pattern SS2 may be larger than the first sub-pattern (SS1 in FIG. 5B), and thus a portion of the first dopant region DR1 may remain under the edge portion of the second sub-pattern SS2.

In the second dopant region DR2, dopants implanted by the second ion implantation process IIP2 and dopants implanted by the first ion implantation process (IIP1 in FIG. 7B) may coexist. That is, a dopant concentration of the second dopant region DR2 may be greater than that of the first dopant region DR1.

The dopant may be either an n-type impurity or a p-type impurity. The n-type impurity may be a group V element. For example, the n-type impurity may be phosphorus (P), arsenic (As), or antimony (Sb). The p-type impurity may be a group III element. For example, the p-type impurity may be boron (B), gallium (Ga), or indium (In). The p-type impurity may be in a form of a molecule including boron (B). For example, the p-type impurity may be BF2.

The method of measuring the overlay may further include performing a series of processes after the second ion implantation process in S70. Certain processes may include sequentially performing a plurality of ion implantation processes. The certain processes may further include forming a corresponding sub-pattern on a mask pattern and an overlay key structure corresponding thereto before performing each of the plurality of ion implantation processes, and checking alignment using the sub-pattern. A size of the sub-pattern may sequentially increase. A difference in width of the sub-pattern in each of a front-end process and a back-end process may be 125 nm to 175 nm. Preferably, the width difference of the sub-pattern may be 150 nm.

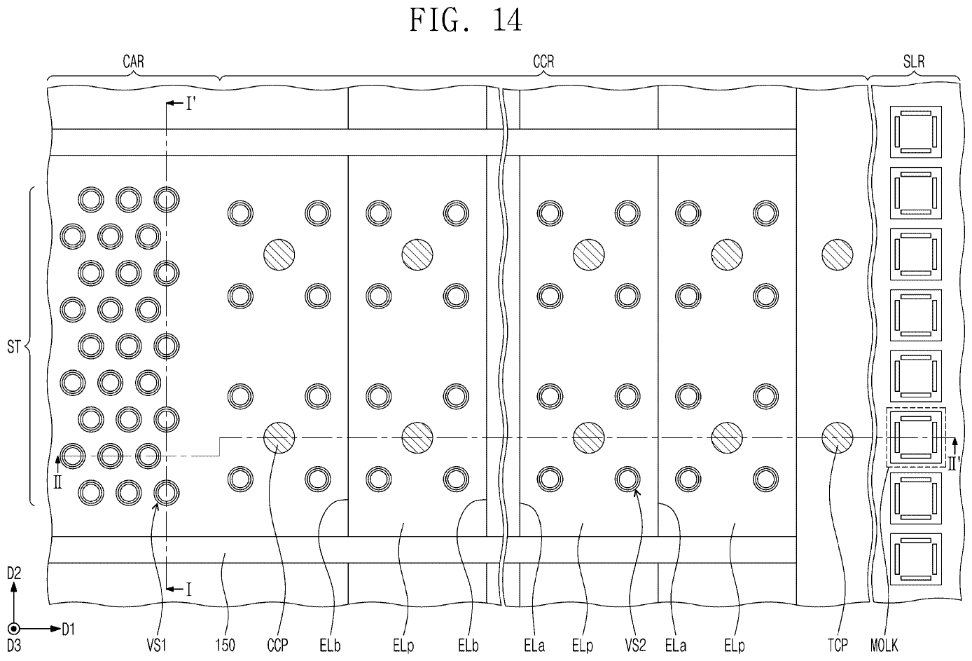

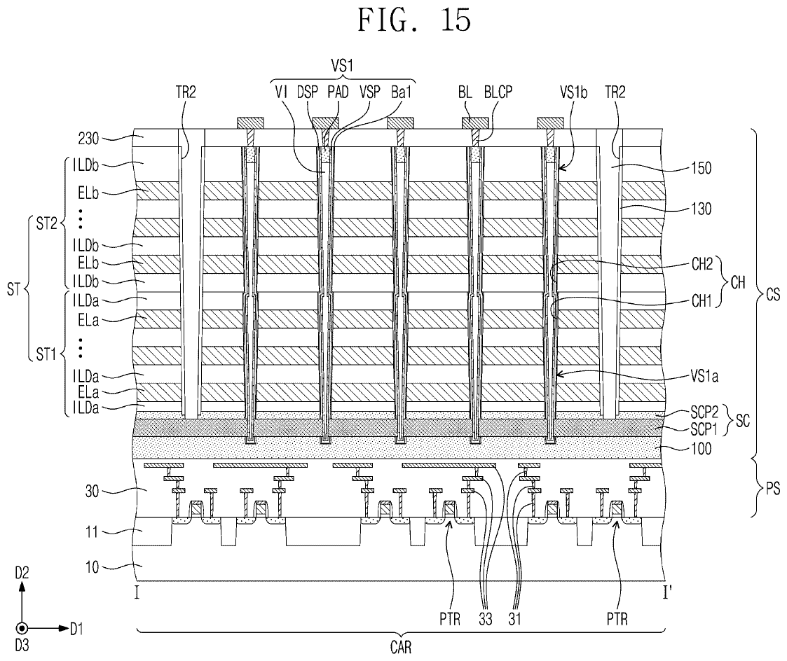

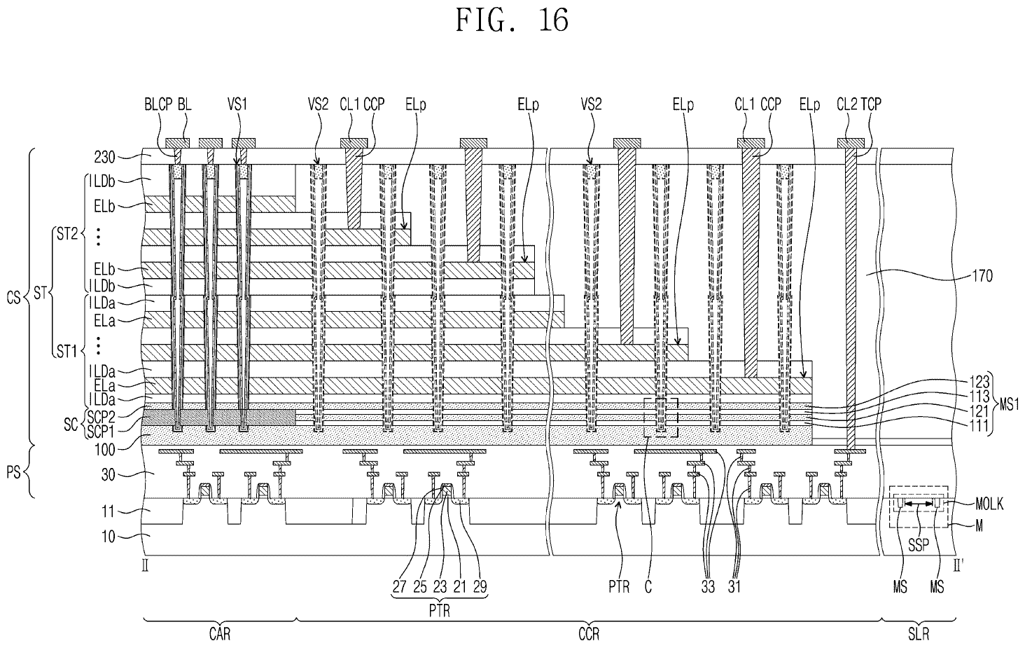

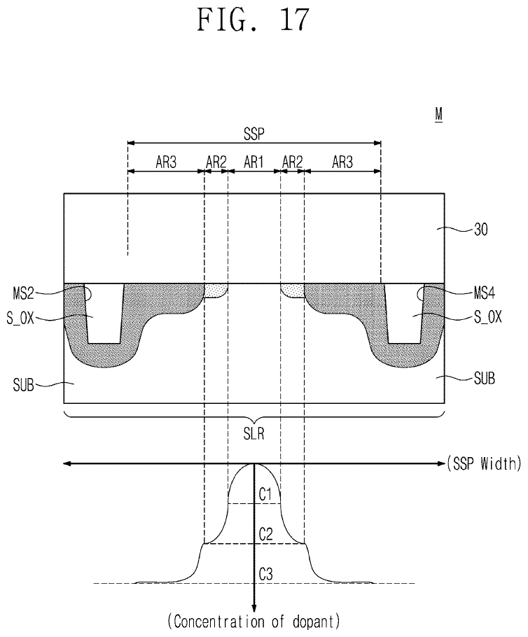

FIG. 14 is a plan view showing a semiconductor memory device including an overlay key structure according to an example embodiment. FIG. 15 is a cross-sectional view taken along line I-I′ of FIG. 14 showing a cell array region including a cell array structure and a peripheral circuit structure on a first substrate. FIG. 16 is a cross-sectional view taken along line II-II′ of FIG. 14 showing a cell array region including a cell array structure and a peripheral circuit structure on a first substrate. FIG. 17 is a cross-sectional view showing a dopant concentration for each region of an overlay key structure.

Referring to FIGS. 14 to 17, a three-dimensional semiconductor memory device may include a first substrate 10, a peripheral circuit structure PS on the first substrate 10, and a cell array structure CS on the peripheral circuit structure PS.

The first substrate 10 including a cell array region CAR, a contact region CCR, and a scribe lane region SLR may be provided. The first substrate 10 may extend from the cell array region CAR to the contact region CCR in a first direction D1 and in a second direction D2 crossing the first direction D1. An upper surface of the first substrate 10 may be orthogonal to a third direction D3 crossing the first and second directions D1 and D2. For example, the first direction D1, the second direction D2, and the third direction D3 may be directions orthogonal to each other.

When viewed in a plan view, the contact region CCR may extend from the cell array region CAR in the first direction D1 (or a direction opposite to the first direction D1). The cell array region CAR may be a region in which vertical channel structures, separation structures, and bit lines electrically connected to the vertical channel structures are provided. The contact region CCR may be a region in which a stepped structure including pad portions ELp, which will be described later, is provided. The contact region CCR may extend from the cell array region CAR in the second direction D2 (or in a direction opposite to the second direction D2).

When viewed in a plan view, the scribe lane region SLR may extend from the contact region CCR in the first direction D1 (or a direction opposite to the first direction D1). The scribe lane region SLR may include a key region where an align key and an overlay key are arranged. The key region may include an overlay key structure MOLK. For example, the overlay key may be an overlay key structure MOLK. The overlay key structure MOLK may be an overlay mark used in ion implantation processes for forming a well.

The first substrate 10 may be, for example, a silicon substrate, a silicon-germanium substrate, a germanium substrate, or a monocrystalline epitaxial layer grown on a monocrystalline silicon substrate. A device isolation layer 11 may be provided in the first substrate 10. The device isolation layer 11 may define an active region of the first substrate 10. The device isolation layer 11 may include, for example, silicon oxide.

The peripheral circuit structure PS may be provided on the first substrate 10. The peripheral circuit structure PS may include peripheral circuit transistors PTR on the active region of the first substrate 10, peripheral contact plugs 31, peripheral circuit wirings 33 electrically connected to the peripheral circuit transistors PTR through peripheral contact plugs 31, and a first insulating layer 30 surrounding them. In an implementation, the peripheral circuit wirings 33 may also be physically connected to the peripheral circuit transistors PTR through the peripheral contact plugs 31.

The peripheral circuit transistors PTR, the peripheral contact plugs 31, and the peripheral circuit wirings 33 may constitute a peripheral circuit. For example, the peripheral circuit transistors PTR may constitute a decoder circuit, a page buffer, and a logic circuit. In an implementation, each of the peripheral circuit transistors PTR may include a peripheral gate insulating layer 21, a peripheral gate electrode 23, a peripheral capping pattern 25, a peripheral gate spacer 27, and peripheral source/drain regions 29.

The peripheral gate insulating layer 21 may be provided between the peripheral gate electrode 23 and the first substrate 10. The peripheral capping pattern 25 may be provided on the peripheral gate electrode 23. The peripheral gate spacer 27 may cover sidewalls of the peripheral gate insulating layer 21, the peripheral gate electrode 23, and the peripheral capping pattern 25. The peripheral source/drain regions 29 may be provided inside the first substrate 10 adjacent to both sides of the peripheral gate electrode 23.

The peripheral circuit wirings 33 may be electrically connected to the peripheral circuit transistors PTR through the peripheral contact plugs 31. Each of the peripheral circuit transistors PTR may be, for example, an NMOS transistor, a PMOS transistor, or a gate-all-around type transistor. For example, widths of the peripheral contact plugs 31 in the first direction D1 or the second direction D2 may increase as a length from the first substrate 10 increases. The peripheral contact plugs 31 and the peripheral circuit wirings 33 may include a conductive material such as metal.

The overlay key structure MOLK may be provided on the first substrate 10. In an implementation, the overlay key structure MOLK may be provided on the scribe lane region SLR of the first substrate 10. The overlay key structure MOLK may include a sub-pattern region SSP, a plurality of main patterns MS, and a buried pattern S_OX on each of the plurality of main patterns MS.

The sub-pattern region SSP may be in a center of the overlay key structure MOLK. The main patterns MS may be patterns embedded into the first substrate 10. In other words, each of the main patterns MS may have a trench shape recessed into the first substrate 10.

An upper surface of the buried pattern S_OX and an upper surface of the first substrate 10 may form a coplanar surface. The buried pattern S_OX may include a silicon oxide layer, or a silicon oxynitride layer. The buried pattern S_OX may be formed at the same time as the device isolation layer 11 of the peripheral circuit structure PS is formed. In other words, the buried pattern S_OX and the device isolation layer 11 may include the same material. The buried pattern S_OX and the device isolation layer 11 may be simultaneously formed by performing a deposition process. The deposition process may be, for example, a chemical vapor deposition (CVD) process, a physical vapor deposition (PVD) process, or an atomic layer deposition (ALD) process.

The plurality of main patterns MS may include a first main pattern, a second main pattern, a third main pattern, and a fourth main pattern. The first main pattern and the third main pattern may face each other in the second direction D2 with the sub-pattern region SSP therebetween when viewed in a plan view. The second main pattern and the fourth main pattern may face each other in the first direction D1 with the sub-pattern region SSP therebetween when viewed in a plan view.

The overlay key structure MOLK may be an overlay mark measuring an overlay for each ion implantation process for forming the peripheral circuit transistors PTR. In an implementation, the ion implantation processes may be implantation processes for forming a triple well, deep N/P type well, source/drain or gate/channel pattern of the peripheral circuit transistors PTR. The ion implantation processes may be performed depending on target values by varying the dose, implantation depth, and type of dopant.

According to the method of measuring the overlay, a size of the sub-pattern provided in the center of the overlay key structure MOLK may increase as the ion implantation process is sequentially performed. Accordingly, a dopant concentration of the sub-pattern region SSP of the overlay key structure MOLK may gradually increase from the center toward the main pattern MS.

Referring back to FIG. 17, the dopant concentration may be different for each region of the overlay key structure MOLK. In an implementation, the dopant concentration may be different for each sub-pattern region SSP of the overlay key structure MOLK. The dopant concentration for each region of the sub-pattern region SSP may increase as it is not blocked by the sub-pattern.

A portion of the sub-pattern region SSP blocked by the first sub-pattern may be defined as a first active region AR1. The first active region AR1 may be a region provided in the center of the sub-pattern region SSP. A portion of the sub-pattern region SSP blocked by the second sub-pattern and excluding the first active region AR1 may be defined as a second active region AR2. The second active region AR2 may be adjacent to the first active region AR1 and may surround the first active region AR1 when viewed in a plan view. A portion of the sub-pattern region SSP between the second active region AR2 and the main patterns MS2 and MS4 may be defined as a third active region AR3.

As the third active region AR3 is not blocked from sub-patterns, the dopant concentration may be higher than those of the first and second active regions AR1 and AR2, respectively. This is because dopants may be repeatedly implanted and overlapped while performing a plurality of ion implantation processes. The second active region AR2 may not be blocked from the second sub-pattern, and thus the dopant concentration thereof may be greater than that of the first active region AR1.

In an implementation, the dopant concentration of the first active region AR1 may be a first concentration C1, the dopant concentration of the second active region AR2 may be a second concentration C2, and the dopant concentration of the third active region AR3 may be a third concentration C3. The third concentration C3 may be greater than the second concentration C2, and the second concentration C2 may be greater than the first concentration C1. For example, the first concentration C1 may be 0 to 5.0×10¹⁰ atoms/cm³. Preferably, the first concentration C1 may be 1.0×10¹⁰ atom/cm³ to 5.0×10¹⁰ atom/cm³. The second concentration C2 may be 4.0×10¹¹ atoms/cm³ to 6.0×10¹¹ atoms/cm³. The third concentration C3 may be 4.0×10¹² atoms/cm³ to 6.0×10¹² atoms/cm³.

The first insulating layer 30 may be provided on the upper surface of the first substrate 10. The first insulating layer 30 may extend from the cell array region CAR to the scribe lane region SLR. The first insulating layer 30 may cover the peripheral circuit transistors PTR, the peripheral contact plugs 31, the peripheral circuit wirings 33, and the overlay key structure MOLK on the first substrate 10. The first insulating layer 30 may include a plurality of insulating layers having a multi-layer structure. For example, the first insulating layer 30 may include silicon oxide, silicon nitride, silicon oxynitride, and/or a low dielectric material.

The cell array structure CS including a second substrate 100 on the first insulating layer 30 and a stack structure ST on the second substrate 100 may be provided. The second substrate 100 may extend in the first direction D1 and the second direction D2. The second substrate 100 may not be provided on a portion of the contact region CCR. The second substrate 100 may be a semiconductor substrate including a semiconductor material. The second substrate 100 may include, e.g., silicon (Si), germanium (Ge), silicon germanium (SiGe), gallium arsenide (GaAs), indium gallium arsenide (InGaAs), or aluminum gallium arsenide (AlGaAs).

The stack structure ST may be provided on the second substrate 100. The stack structure ST may extend from the cell array region CAR to the contact region CCR. A plurality of stack structures ST may be provided, and a plurality of stack structures ST may be arranged in the second direction D2, with a separation structure 150 therebetween in the second direction D2, as will be described later. Hereinafter, for convenience of description, a single stack structure ST will be described, but the following description may also be applied to other stack structures ST.

The stack structure ST may include alternately stacked interlayer insulating layers ILDa and ILDb and gate electrodes ELa and ELb. The gate electrodes ELa and ELb may correspond to word lines.

In more detail, the stack structure ST may include a first stack structure ST1 on the second substrate 100 and a second stack structure ST2 on the first stack structure ST1. The first stack structure ST1 may include alternately stacked first interlayer insulating layers ILDa and first gate electrodes ELa, and the second stack structure ST2 may include alternately stacked second interlayer insulating layers ILDb and second gate electrodes ELb. A thickness of each of the first and second gate electrodes ELa and ELb in the third direction D3 may be substantially the same. Hereinafter, reference to thickness will be to a thickness in the third direction D3.

Lengths of the first and second gate electrodes ELa and ELb in the first direction D1 may decrease as a length from the second substrate 100 increases (i.e., in the third direction D3). In other words, a length of each of the first and second gate electrodes ELa and ELb in the first direction D1 may be greater than a length of an electrode directly above the corresponding electrode in the first direction D1. A lowermost one of the first gate electrodes ELa of the first stack structure ST1 may have the longest length in the first direction D1, and an uppermost one of the second gate electrodes ELb of the second stack structure ST2 may have the smallest length in the first direction D1.

The first and second gate electrodes ELa and ELb may have pad portions ELp on the contact region CCR. The pad portions ELp of the first and second gate electrodes ELa and ELb may be horizontally and vertically disposed at different positions. The pad portions ELp may form a stepped structure in the first direction D1.

Due to the stepped structure, a thickness of each of the first and second stack structures ST1 and ST2 decreases as a length from the outer-most one of the first vertical channel structures VS1 (described later) increases. Sidewalls of the first and second gate electrodes ELa and ELb may be spaced apart from each other at regular intervals in the first direction D1 when viewed in a plan view.

The first and second gate electrodes ELa and ELb may include at least one of, for example, a doped semiconductor (e.g., doped silicon, etc.), a metal (e.g., tungsten, copper, aluminum, etc.), a conductive metal nitride (e.g., titanium nitride, tantalum nitride, etc.) and transition metals (e.g., titanium, tantalum, etc.). The first and second gate electrodes ELa and ELb may more preferably include tungsten.

The first and second interlayer insulating layers ILDa and ILDb may be provided between the first and second gate electrodes ELa and ELb, and a sidewall may be aligned with one of the first and second gate electrodes ELa and ELb in contact with a lower portion of each of the first and second gate electrodes ELa and ELb. That is, similar to the first and second gate electrodes ELa and ELb, lengths of the first and second interlayer insulating layers ILDa and ILDb in the first direction D1 may decrease as a length from the second substrate 100 increases.

A lowermost one of the second interlayer insulating layers ILDb may be in contact with an uppermost one of the first interlayer insulating layers ILDa. For example, a thickness of each of the first and second interlayer insulating layers ILDa and ILDb may be smaller than a thickness of each of the first and second gate electrodes ELa and ELb. For example, a thickness of a lowermost one of the first interlayer insulating layers ILDa may be smaller than a thickness of each of the other interlayer insulating layers ILDa and ILDb. For example, a thickness of an uppermost one of the second interlayer insulating layers ILDb may be greater than a thickness of each of the other interlayer insulating layers ILDa and ILDb.

Except for the lowermost one of the first interlayer insulating layers ILDa and the uppermost one of the second interlayer insulating layers ILDb, each of the other interlayer insulating layers ILDa and ILDb may have substantially the same thickness. However, this is merely exemplary, and the thicknesses of the first and second interlayer insulating layers ILDa and ILDb may be varied depending on characteristics of the semiconductor device.

The first and second interlayer insulating layers ILDa and ILDb may include, for example, silicon oxide, silicon nitride, silicon oxynitride, and/or a low-k material. For example, the first and second interlayer insulating layers ILDa and ILDb may include HDP oxide or tetraethyl orthosilicate (TEOS).

A source structure SC may be provided between the second substrate 100 on the cell array region CAR and the lowermost one of the first interlayer insulating layers ILDa. The source structure SC may include a first source conductive pattern SCP1 and a second source conductive pattern SCP2 sequentially stacked on the second substrate 100. The second source conductive pattern SCP2 may be provided between the first source conductive pattern SCP1 and the lowermost one of the first interlayer insulating layers ILDa. A thickness of the first source conductive pattern SCP1 may be greater than that of the second source conductive pattern SCP2. The first and second source conductive patterns SCP1 and SCP2 may include a semiconductor material such as silicon or a semiconductor material doped with impurities. When the first and second source conductive patterns SCP1 and SCP2 include a semiconductor material doped with impurities, an impurity concentration of the first source conductive pattern SCP1 may be greater than that of the second source conductive pattern SCP2.

The first source conductive pattern SCP1 of the source structure SC may be provided only on the cell array region CAR and may not be provided on the contact region CCR. However, the second source conductive pattern SCP2 of the source structure SC may extend from the cell array region CAR to the contact region CCR. The second source conductive pattern SCP2 on the contact region CCR may be referred to as a second semiconductor layer 123.

A first mold structure MS1 may be provided between the second substrate 100 on the contact region CCR and the lowermost one of the first interlayer insulating layers ILDa. The first mold structure MS1 may include a first buffer insulating layer 111, a first semiconductor layer 121, a second buffer insulating layer 113, and a second semiconductor layer 123, which may be sequentially stacked on the second substrate 100.

The first semiconductor layer 121 may be provided between the second substrate 100 and the second semiconductor layer 123. The first buffer insulating layer 111 may be provided between the second substrate 100 and the first semiconductor layer 121, and the second buffer insulating layer 113 may be provided between the first semiconductor layer 121 and the second semiconductor layer 123. A lower surface of the first buffer insulating layer 111 may be substantially coplanar with a lower surface of the first source conductive pattern SCP1. An upper surface of the second buffer insulating layer 113 may be substantially coplanar with an upper surface of the first source conductive pattern SCP1.

The first and second buffer insulating layers 111 and 113 may include, for example, silicon oxide. The first and second semiconductor layers 121 and 123 may include a material having an etch selectivity with respect to a first barrier pattern Bal. The first and second semiconductor layers 121 and 123 may include, for example, a semiconductor material such as silicon.

A plurality of first vertical channel structures VS1 may be provided on the cell array region CAR and penetrating the stack structure ST and the source structure SC. The first vertical channel structures VS1 may pass through at least a portion of the second substrate 100, and a lower surface of each of the first vertical channel structures VS1 may be positioned at a lower level than an upper surface of the second substrate 100 and a lower surface of the source structure SC. That is, the first vertical channel structures VS1 may be in direct contact with the second substrate 100.

The first vertical channel structures VS1 may be arranged in a zigzag shape in the first direction D1 or the second direction D2 when viewed in a plan view of FIG. 15. The first vertical channel structures VS1 may not be provided on the contact region CCR. The first vertical channel structures VS1 may correspond to channels of memory cell transistors.

The first vertical channel structures VS1 may be provided in vertical channel holes CH penetrating the stack structure ST. Each of the vertical channel holes CH may include a first vertical channel hole CH1 penetrating the first stack structure ST1 and a second vertical channel hole CH2 penetrating the second stack structure ST2. The first and second vertical channel holes CH1 and CH2 of each of the vertical channel holes CH may be connected to each other in the third direction D3.

Each of the first vertical channel structures VS1 may include a first portion VS1a and a second portion VS1b. The first portion VS1a may be provided in the first vertical channel hole CH1, and the second portion VS1b may be provided in the second vertical channel hole CH2. The second portion VS1b may be provided on the first portion VS1a and may be connected to each other.

Each of the first portion VS1a and the second portion VS1b may have a width increasing in the first direction D1 or the second direction D2 toward the third direction D3. An uppermost width of the first portion VS1a may be greater than a lowermost width of the second portion VS1b. In other words, each sidewall of the first vertical channel structures VS1 may have a step at an interface between the first portion VS1a and the second portion VS1b. Each sidewall of the first vertical channel structures VS1 may have three or more steps at different levels, and a sidewall of each of the first vertical channel structures VS1 may be flat without a step.

Each of the first vertical channel structures VS1 may include a first barrier pattern Bal, a data storage pattern DSP and vertical semiconductor pattern (VSP) which may be sequentially provided on inner walls of each of the vertical channel holes CH, a buried insulating pattern VI filling an inner space surrounded by the vertical semiconductor pattern VSP, and a conductive pad PAD on the buried insulating pattern VI. The conductive pad PAD may be provided in a space surrounded by the buried insulating pattern VI and the data storage pattern DSP (or the vertical semiconductor pattern VSP). An upper surface of each of the first vertical channel structures VS1 may have, for example, a circular shape, an elliptical shape, or a bar shape. The first barrier pattern Bal may be adjacent to the stack structure ST and cover sidewalls of the first and second interlayer insulating layers ILDa and ILDb and sidewalls of the first and second gate electrodes ELa and ELb. The data storage pattern DSP may conformally cover an inner wall of the first barrier pattern Bal. The vertical semiconductor pattern VSP may conformally cover an inner wall of the data storage pattern DSP.

The data storage pattern DSP may be provided between the first barrier pattern Bal and the vertical semiconductor pattern VSP. The vertical semiconductor pattern VSP may be provided between the data storage pattern DSP and the buried insulating pattern VI. The vertical semiconductor pattern VSP may have a pipe shape or a macaroni shape with a closed lower end. The first barrier pattern Bal and the data storage pattern DSP may have a pipe shape or a macaroni shape with an open lower end.

The first barrier pattern Bal may include a high-k material having a higher dielectric constant than silicon oxide and silicon nitride. The first barrier pattern Bal may include at least one of, for example, hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, and barium titanium oxide, strontium titanium oxide, lithium oxide, aluminum oxide, lead scandium tantalum oxide, and lead zinc niobate. The first barrier pattern Bal may more preferably include aluminum oxide or hafnium oxide.

The vertical semiconductor pattern VSP may include, for example, a semiconductor material doped with impurities, an intrinsic semiconductor material not doped with impurities, or a polycrystalline semiconductor material. The vertical semiconductor pattern VSP may be in contact with a portion of the source structure SC. The conductive pad PAD may include, for example, a semiconductor material doped with impurities or a conductive material.

A plurality of second vertical channel structures VS2 may be provided on the contact region CCR to pass through the second insulating layer 170, the stack structure ST and the first mold structure MS1. In an implementation, the second vertical channel structures VS2 may pass through the pad portions ELp of the first and second gate electrodes ELa and ELb. The second vertical channel structures VS2 may be provided around cell contact plugs CCP, which will be described later. The second vertical channel structures VS2 may not be provided on the cell array region CAR. The second vertical channel structures VS2 may be formed at the same time as the first vertical channel structures VS1 and may have substantially the same structure. However, according to embodiments, the second vertical channel structures VS2 may not be provided.

A second insulating layer 170 covering a portion of the stack structure ST and the first insulating layer 30 may be provided on the contact region CCR. In an implementation, the second insulating layer 170 may be provided on the pad portions ELp of the first and second gate electrodes ELa and ELb while covering the stepped structure of the stack structure ST. The second insulating layer 170 may have a substantially flat upper surface. An upper surface of the second insulating layer 170 may be substantially coplanar with an upper surface of the stack structure ST. In an implementation, the upper surface of the second insulating layer 170 may be substantially coplanar with an upper surface of an uppermost one of the second interlayer insulating layers ILDb of the stack structure ST.

The second insulating layer 170 may include one insulating layer or a plurality of stacked insulating layers. The second insulating layer 170 may include, for example, an insulating material such as silicon oxide, silicon nitride, silicon oxynitride, and/or a low dielectric material. The second insulating layer 170 may include an insulating material different from that of the first and second interlayer insulating layers ILDa and ILDb of the stack structure ST. For example, when the first and second interlayer insulating layers ILDa and ILDb of the stack structure ST include high-density plasma oxide, the second insulating layer 170 may include TEOS.

A third insulating layer 230 may be provided on the second insulating layer 170 and the stack structure ST. The third insulating layer 230 may cover the upper surface of the second insulating layer 170, the upper surface of the uppermost one of the second interlayer insulating layers ILDb of the stack structure ST, and upper surfaces of the first and second vertical channel structures VS1 and VS2.

The third insulating layer 230 may include one insulating layer or a plurality of stacked insulating layers. The third insulating layer 230 may include, for example, silicon oxide, silicon nitride, silicon oxynitride, and/or a low dielectric material. The third insulating layer 230 may include, for example, substantially the same insulating material as the second insulating layer 170, and may include an insulating material different from those of the first and second interlayer insulating layers ILDa and ILDb of the stack structure ST.

Bit line contact plugs BLCP passing through the third insulating layer 230 and connected to the first vertical channel structures VS1 may be provided. Cell contact plugs CCP may be provided through the third insulating layer 230 and the second insulating layer 170 and connected to the first and second gate electrodes ELa and ELb, respectively. Each of the cell contact plugs CCP may pass through one of the first and second interlayer insulating layers ILDa and ILDb, and may directly connect one of the pad parts ELp of the first and second gate electrodes ELa and ELb. Each of the cell contact plugs CCP may be adjacent to the plurality of second vertical channel structures VS2 and may be spaced apart from each other.

A peripheral contact plug TCP electrically connected to the peripheral circuit transistors PTR of the peripheral circuit structure PS through at least a portion of the third insulating layer 230, the second insulating layer 170, and the first insulating layer 30 may be provided. The peripheral contact plug TCP may be provided in plural. The peripheral contact plug TCP may be spaced apart from the second substrate 100, the source structure SC, and the stack structure ST in the first direction D1.

For example, widths in the first or second direction D1 or D2 of the bit line contact plugs BLCP, the cell contact plugs CCP, and the peripheral contact plug TCP may increase in the third direction D3.

Bit lines BL connected to corresponding bit line contact plugs BLCP may be provided on the third insulating layer 230. First conductive lines CL1 connected to the cell contact plugs CCP and second conductive lines CL2 connected to the peripheral contact plug TCP may be provided on the third insulating layer 230.

The bit line contact plugs BLCP, the cell contact plugs CCP, the peripheral contact plug TCP, the bit lines BL, and the first and second conductive lines CL1 and CL2 may include, for example, a conductive material such as metal. Additional wirings and additional vias electrically connected to the bit lines BL and the first and second conductive lines CL1 and CL2 may be further provided on the third insulating layer 230.

When the stack structure ST is provided in plural, the separation structure 150 may be provided in a second trench TR2 crossing between the plurality of stack structures ST in the first direction D1. The separation structure 150 may be spaced apart from the first and second vertical channel structures VS1 and VS2 in the second direction D2. An upper surface of the separation structure 150 may be positioned at a higher level than upper surfaces of the first and second vertical channel structures VS1 and VS2, for example. A lower surface of the separation structure 150 may be substantially coplanar with an upper surface of the first source conductive pattern SCP1 and may be positioned at a higher level than the upper surface of the second substrate 100.

The separation structure 150 may be provided in plural, and a plurality of separation structures 150 may be spaced apart from each other in the second direction D2 with the stack structure ST therebetween. A separation spacer 130 may be provided between the separation structure 150 and the stack structure ST and surround the separation structure 150. The separation spacer 130 may conformally cover sidewalls of the first and second interlayer insulating layers ILDa and ILDb and the first and second gate electrodes ELa and ELb. The separation structure 150 may include, for example, silicon oxide. The separation spacer 130 may include a material having an etch selectivity with respect to the second source conductive pattern SCP2 and the first and second semiconductor layers 121 and 123. The separation spacer 130 may include, for example, silicon nitride.

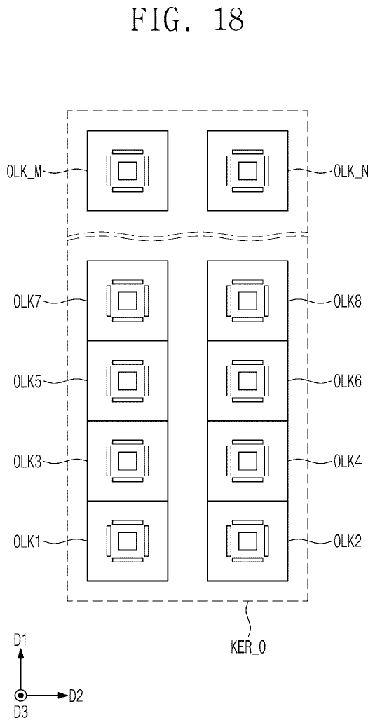

FIG. 18 is a view showing a conventional key region of a semiconductor memory device according to an example embodiment. Referring to FIG. 18, a three-dimensional semiconductor memory device and the conventional three-dimensional semiconductor memory device may be compared. A plurality of overlay keys OLK1, OLK2, OLK3, . . . , OLK_M, and OLK_N may be formed on the conventional key region KER_O. Each of the plurality of overlay keys OLK1, OLK2, OLK3, . . . , OLK_M, and OLK_N may be used to measure an overlay after each of repeated ion implantation processes is performed. In other words, the first overlay key OLK1 may be used to measure overlay after a first ion implantation process, and the second overlay key OLK2 may be used to measure overlay after a second ion implantation process. The M^{th} overlay key OLK_M may be used to measure overlay after an M^{th} ion implantation process, and the Nth overlay key OLK_N may be used to measure overlay after an Nth ion implantation process.

Each of the plurality of overlay keys OLK1, OLK2, OLK3, . . . , OLK_M, and OLK_N may have the same size. Widths of each of the plurality of overlay keys OLK1, OLK2, OLK3, . . . , OLK_M and OLK_N in the first direction D1 and in the second direction D2 may range from 32.5 μm to 37.5 μm. That is, each of the overlay key structure (MOLK in FIG. 3) and the plurality of overlay keys OLK1, OLK2, OLK3, . . . , OLK_M, and OLK_N may have the same size as each other.

As the conventional key region KER_O uses different overlay keys OLK1, OLK2, OLK3, . . . , OLK_M, and OLK_N for each ion implantation process, the area occupied by the overlay keys OLK1, OLK2, OLK3, . . . , OLK_M, and OLK_N in the scribe lane region (SLR in FIG. 5) of the substrate (SUB in FIG. 5) may be greater than the area occupied by the overlay key structure (MOLK in FIG. 3). That is, using the overlay key structure (MOLK) may increase utilization of the scribe lane region (SLR in FIG. 5). That is, as an empty space in the scribe lane region (SLR of FIG. 5) increases, a three-dimensional semiconductor memory device with an improved integration may be provided.

In the method of measuring the overlay, while the ion implantation processes are repeatedly performed, the size of the sub-pattern of the overlay key structure may be increased in the subsequent process than in the previous process. Accordingly, the overlay measurement may be accurately performed by blocking the surface of the sub-pattern region damaged by the previous ion implantation process into the sub-pattern. That is, as the surface of the damaged sub-pattern region with the sub-pattern is blocked, it may be possible to obtain the overlay measurement image having the constant brightness, thereby performing the accurate overlay measurement based thereon.

The three-dimensional semiconductor memory device may perform the overlay measurement process using one overlay key structure during performing the repeated ion implantation processes. As the one overlay key structure may be used for the plurality of ion implantation processes, the space occupied on the scribe lane region in the substrate may be reduced. That is, the integration of the three-dimensional semiconductor memory device may be improved.

By way of summation and review, to meet the increased demand for electronic devices with fast speed and/or low power consumption, it may be desirable for semiconductor devices to have high reliability, high performance, and/or multiple functions. To satisfy these technical requirements, complexity and/or integration density of semiconductor devices may be increased.

As integration of semiconductor devices increases, a density of patterns formed on a unit area of a substrate increases. In addition, as the semiconductor devices become multi-functional and high-performance, the number of layers formed on the substrate increases. Accordingly, it may be desirable to accurately form patterns at predetermined positions during a manufacturing process of a semiconductor device. Accordingly, an alignment key or an overlay key for aligning layers stacked on the substrate is used.

An overlay measurement process may be a process of determining a degree of misalignment between a lower pattern and an upper pattern on a substrate. The overlay measurement process may include a process of inspecting whether positions of patterns match well after exposure. The overlay measurement process may be performed by measuring overlay marks. The overlay mark may be of a box-in-box type. The overlay measurement process may be classified depending on a method of reading an overlay mark. The method of reading the overlay mark may be image based overlay (IBO) or diffraction based overlay (DBO). Through the overlay measurement process, various overlay measurement values may be obtained at various positions on the substrate. A plurality of overlay measurement values may appear differently at each position. A method of accurately measuring overlay is disclosed. A three-dimensional memory semiconductor device with an improved integration is disclosed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made.

What is claimed is:

1. A method of measuring overlay, comprising:
forming an active region on a cell region of a substrate and forming at least one overlay key structure on a scribe lane region of the substrate;
forming a first mask pattern on the active region and forming a first sub-pattern on the overlay key structure;
checking an alignment using the first sub-pattern;
performing a first ion implantation process into the substrate;
forming a second mask pattern on the active region and forming a second sub-pattern on the overlay key structure;
checking the alignment using the second sub-pattern; and
performing a second ion implantation process into the substrate,
wherein a second width of the second sub-pattern is greater than a first width of the first sub-pattern.

2. The method as claimed in claim 1, wherein a difference between the second width and the first width is 125 nm to 175 nm.

3. The method as claimed in claim 1, wherein:
the forming of the overlay key structure includes forming trenches equally spaced apart on the scribe lane region and forming a sub-pattern region between the trenches,
the first sub-pattern and the second sub-pattern are both on the sub-pattern region, and
the trenches are a plurality of main patterns.

4. The method as claimed in claim 3, wherein:
each of the plurality of main patterns are spaced apart from each other, and
each of the plurality of main patterns are spaced apart from the sub-pattern region.

5. The method as claimed in claim 1, wherein the forming of the first mask pattern on the active region and the forming of the first sub-pattern on the overlay key structure includes positioning the first sub-pattern on a center of the overlay key structure.

6. The method as claimed in claim 5, wherein the checking of the alignment using the first sub-pattern includes:
obtaining a first image for the overlay key structure; and
determining whether the first sub-pattern is in the center of the overlay key structure based on the first image.

7. The method as claimed in claim 6, wherein the checking of the alignment using the first sub-pattern further includes reworking the first mask pattern and the first sub-pattern when the first sub-pattern is not in the center of the overlay key structure.

8. The method as claimed in claim 1, wherein the forming of the second mask pattern on the active region and the forming of the second sub-pattern on the overlay key structure includes:
removing the first mask pattern and the first sub-pattern; and
positioning the second sub-pattern on a center of the overlay key structure.

9. The method as claimed in claim 8, wherein the checking of the alignment using the second sub-pattern includes:
obtaining a second image for the overlay key structure; and
determining whether the second sub-pattern is in the center of the overlay key structure based on the second image.

10. The method as claimed in claim 9, wherein the checking of the alignment using the second sub-pattern further includes reworking the second mask pattern and the second sub-pattern when the second sub-pattern is not in the center of the overlay key structure.

11. The method as claimed in claim 9, wherein the second image has a constant brightness.

12. The method as claimed in claim 1, further comprising sequentially performing the first ion implantation processes before the second ion implantation process.

13. A semiconductor device, comprising:
a substrate including a key region; and
an overlay key structure on the key region, wherein:
the overlay key structure includes a sub-pattern region and a plurality of main patterns spaced apart from each other,
each of the plurality of main patterns being spaced apart from the sub-pattern region, the sub-pattern region including:
a first region provided in a center of the overlay key structure;
a second region adjacent to the first region and surrounding the first region; and
a third region between the second region and the plurality of main patterns, a third dopant concentration in the third region being greater than a first dopant concentration in the first region and a second dopant concentration in the second region.

14. The semiconductor device as claimed in claim 13, wherein the second dopant concentration of the second region is greater than the first dopant concentration of the first region.

15. The semiconductor device as claimed in claim 13, wherein:
the first dopant concentration of the first region is 1.0×10¹⁰ atom/cm³ to 5.0×10¹⁰ atom/cm³,
the second dopant concentration of the second region is 4.0×10¹¹ atom/cm³ to 6.0×10¹¹ atom/cm³, and
the third dopant concentration of the third region is 4.0×10¹³ atom/cm³ to 6.0×10¹³ atom/cm³.

16. A three-dimensional semiconductor memory device, comprising:
a substrate including a cell array region, a contact region, and a scribe lane region;
a peripheral circuit structure on the cell array region and the contact region, and a cell array structure on the peripheral circuit structure; and
an overlay key structure on the scribe lane region, the cell array structure including:
a stack structure including interlayer insulating layers alternately and repeatedly stacked on the peripheral circuit structure and gate electrodes between the interlayer insulating layers; and
vertical channel structures provided in vertical channel holes penetrating the stack structure, each of the vertical channel structures including a charge storage layer, a tunneling insulating layer, and a vertical semiconductor pattern sequentially covering inner walls of each of the vertical channel holes,
the overlay key structure including a sub-pattern region and a main pattern spaced apart from the sub-pattern region, and a buried pattern on the main pattern, and
a dopant concentration of the sub-pattern region gradually increasing from a center thereof toward the main pattern.

17. The three-dimensional semiconductor memory device as claimed in claim 16, wherein the main pattern has a trench shape recessed into the substrate.

18. The three-dimensional semiconductor memory device as claimed in claim 16, wherein:
the buried pattern includes a silicon oxide layer, a silicon oxynitride layer, or a combination thereof, and
a buried pattern upper surface is coplanar with a substrate upper surface.

19. The three-dimensional semiconductor memory device as claimed in claim 16, wherein the peripheral circuit structure includes:
active regions on the cell array region and the contact region;
a device isolation layer defining the active regions;
peripheral circuit transistors on the active regions;
peripheral circuit wirings electrically connected to the peripheral circuit transistors;
peripheral contact plugs physically connecting the peripheral circuit wirings and the peripheral circuit transistors; and
an insulating layer covering the peripheral circuit transistors, the peripheral circuit wirings, and the peripheral contact plugs.

20. The three-dimensional semiconductor memory device as claimed in claim 19, wherein:
the device isolation layer and the buried pattern are simultaneously formed by a deposition process,
the insulating layer extends to the scribe lane region, and
the insulating layer covers the overlay key structure.
